(19) United States
(12) Patent Application Publication
(10) Pub. No.: US 2025/0239531 A1
(43) Pub. Date: Jul. 24, 2025

(54) ELECTRONIC DEVICE AND A METHOD FOR FORMING THE SAME

(71) Applicant: STATS ChipPAC Pte. Ltd., Singapore (SG)

(72) Inventors: TaeWoo LEE, Incheon (KR); HeeSoo LEE, Incheon (KR); EunHee MYUNG, Gyeonggi-do (KR); KyungEun KIM, Incheon (KR)

(21) Appl. No.: 19/034,566

(22) Filed: Jan. 23, 2025

(30) Foreign Application Priority Data
Jan. 24, 2024 (CN) 202410100932.7

(51) Int. Cl. H01L 23/538; H01L 21/48; H01L 23/14; H01L 23/31; H01L 25/00; H01L 25/07

(52) U.S. Cl. CPC H01L 23/5385; H01L 21/4846; H01L 23/5386; H01L 25/071; H01L 25/50; H01L 23/147; H01L 23/3107; H01L 2225/06513; H01L 2225/06517; H01L 2225/06562

(57) ABSTRACT

An electronic device and a method for forming the same are provided. The method comprises: providing a package substrate; forming a bridge interposer within the package substrate and exposing a top surface of the bridge interposer; attaching a step interposer on the top surface of the bridge interposer, wherein the step interposer defines a step structure; mounting a bottom semiconductor die on the package substrate and adjacent to the step interposer; mounting one or more upper semiconductor dice on both of the bottom semiconductor die and the step structure of the step interposer to electrically couple each of the one or more upper semiconductor dice with the bridge interposer; mounting an electronic component on the top surface of the bridge interposer to electrically couple the electronic component with the one or more upper semiconductor dice; and forming a mold cap on the package substrate.

### TECHNICAL FIELD

The present application generally relates to semiconductor packaging technology, and more particularly, to an electronic device and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, System on a Chip (SOC) modules are widely used in integrated electronic devices. Typically, in some high-performance devices, the SOC modules can be packaged in conjunction with various semiconductor modules to provide better performance and multi-functionality. However, it is noted that fabrication processes of semiconductor packages which incorporate SOC modules and other semiconductor modules may be complicated and not cost effective. Also, such complicated processes may adversely affect the device performance of the semiconductor packages incorporating such modules.

Therefore, a need exists for further improvement of a method for forming an electronic device incorporating SOC modules.

### SUMMARY OF THE INVENTION

An objective of the present application is to provide an electronic device and a method for forming an electronic device of higher performance and with a simple process.

According to an aspect of the present application, a method for forming an electronic device is provided. The method comprises: providing a package substrate; forming a bridge interposer within the package substrate and exposing a top surface of the bridge interposer from the package substrate; attaching a step interposer on the top surface of the bridge interposer, wherein the step interposer defines a step structure on one side of the step interposer; mounting a bottom semiconductor die on the package substrate and adjacent to the step interposer; mounting one or more upper semiconductor dice on both of the bottom semiconductor die and the step structure of the step interposer to electrically couple each of the upper semiconductor dice with the bridge interposer through the step interposer; mounting an electronic component on the top surface of the bridge interposer to electrically couple the electronic component with the upper semiconductor dice via the bridge interposer and the step interposer; and forming a mold cap on the package substrate to encapsulate the bottom semiconductor die, the upper semiconductor dice, the step interposer and the electronic component.

According to another aspect of the present application, an electronic device is provided. The electronic device comprises: a package substrate; a bridge interposer formed within the package substrate, wherein the bridge interposer comprises a top surface exposed from the package substrate; a step interposer attached on the top surface of the bridge interposer, wherein the step interposer defines a step structure on one side of the step interposer; a bottom semiconductor die mounted on the package substrate and adjacent to the step interposer; one or more upper semiconductor dice mounted on both of the bottom semiconductor die and the step structure of the step interposer, wherein each of the upper semiconductor dice is electrically coupled with the bridge interposer through the step interposer; an electronic component mounted on the top surface of the bridge interposer, wherein the electronic component is electrically coupled with the upper semiconductor dice via the bridge interposer and the step interposer; and a mold cap formed on the package substrate and encapsulating the bottom semiconductor die, the upper semiconductor dice, the step interposer and the electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1G illustrate various steps of a method for forming an electronic device according to a first embodiment of the present application.

FIG. 2 illustrates an electronic device according to a second embodiment of the present application.

FIG. 3 illustrates an electronic device according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, System on a Chip (SOC) module(s) and various semiconductor modules may be incorporated into a single device to provide better performance and multi-functionality. During a fabrication process of the device, the semiconductor modules may be pre-molded before being mounted onto a package substrate. Then the pre-molded semiconductor modules and the SOC module(s) may be mounted onto the package substrate separately. Next, a mold cap may be formed on the package substrate to encapsulate all of the pre-molded semiconductor modules and the SOC modules, thereby forming the integrated device. However, it is noted that the fabrication processes of the integrated device may be complicated and not cost effective. Also, the pre-molded semiconductor modules within the integrated device forms a package-in-package structure, which may induce warpage of the whole device and adversely affect the device performance. To address this issue, a new method for forming an electronic device is provided, which introduces a step interposer with a step structure on a package substrate. Two or more semiconductor dice may be mounted on the package substrate and on the step structure of the step interposer in a stepwise manner. The semiconductor dice then may be electrically coupled with the SOC modules at least partially through the step interposer. As such, a one-step encapsulation may be implemented to form an integral mold cap for the entire device.

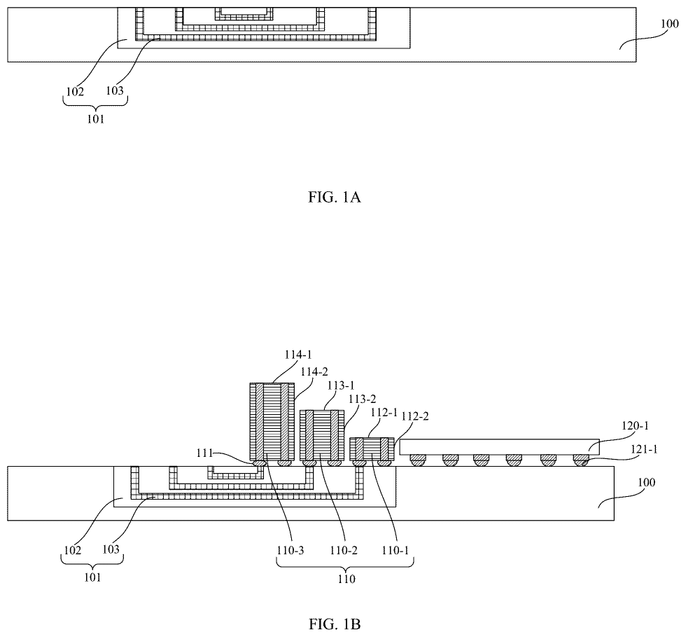

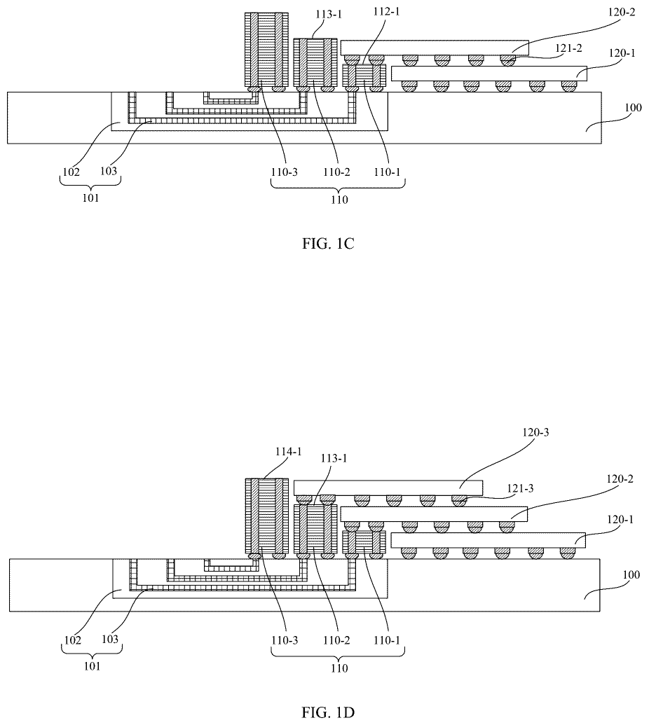

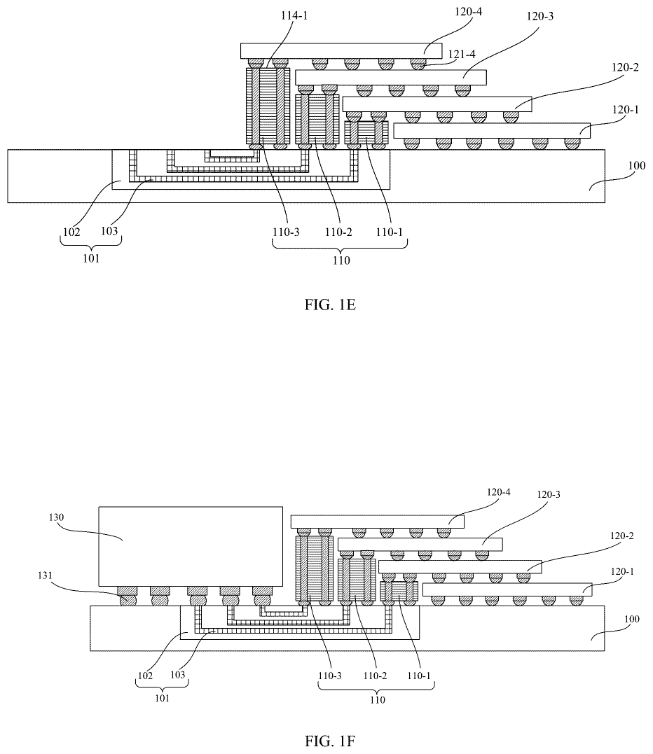

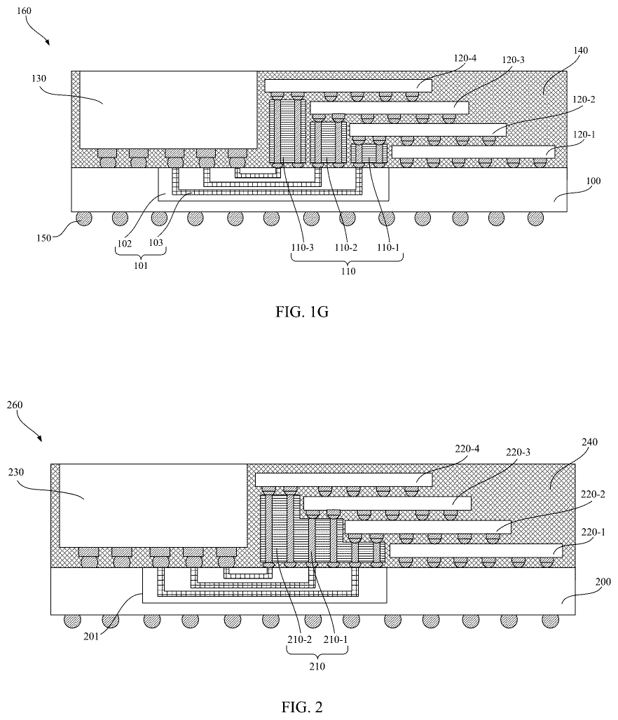

FIGS. 1A to 1G illustrate various steps of a method for forming an electronic device according to a first embodiment of the present application. In the following, the method will be described with reference to FIGS. 1A to 1G in more details.

As shown in FIG. 1A, a package substrate 100 having a front surface and a back surface is provided. The front surface of the package substrate 100 may serve as a platform where electronic component(s) and interposer(s) can be mounted. In some embodiments, the electronic device may be a double sided molding (DSM) package, and accordingly, the back surface may also serve as another platform where other electronic component(s) and interposer(s) may be mounted.

Next, a cavity is formed within the package substrate 100, and a bridge interposer 101 is formed within the cavity. A top surface of the bridge interposer 101 is exposed from the package substrate 100 for mounting electronic component(s) and/or interposer(s). In some embodiments, the bridge interposer 101 may provide electrical connections between the electronic component(s) and the interposer(s). In the embodiment shown in FIG. 1A, the bridge interposer 101 may include at least one conductive wire 103 which is surrounded by an interposer base 102. The interposer base 102 may include a dielectric material such as silicon dioxide or a semiconductor material such as silicon, or may include other dielectric materials such as epoxy resin or similar polymer materials. Each of the conductive wire(s) 103 may have a first conductive pad on one end and a second conductive pad on the other end, and the first conductive pad and the second conductive pad are both exposed from the top surface of the bridge interposer 101, with a main section of the conductive wire 103 that connects the two ends embedded in the interposer base 102. In some embodiments, the number of the conductive wires 103 included in the bridge interposer 101 may be two, three or even more, depending on the number of the electronic component(s) and the interposer(s) attached on the bridge interposer 101 and requiring electrical connection with other components.

In some embodiments, apart from the bridge interposer 101, redistribution structures (not shown) may also be formed in the package substrate 100, which may include a plurality of top conductive patterns, a plurality of bottom conductive patterns, and a plurality of conductive vias electrically connecting at least one of the top conductive patterns with at least one of the bottom conductive patterns. Multiple sets of conductive pads can be formed on the top conductive patterns and bottom conductive patterns for the mounting of the electronic component(s) and interposer(s). It can be appreciated that the multiple sets of conductive pads may be exposed portions of conductive patterns formed within the package substrate 100. In some embodiments, the redistribution structures can be optionally connected with the bridge interposer 101.

Next, as shown in FIG. 1B, a plurality of connecting interposer units having successively increasing heights are juxtaposed on the top surface of the bridge interposer 101 via solder bumps 111. The connecting interposer units together form a step interposer 110. Each of the connecting interposers may be an e-bar module, which includes multiple conductive pillars and a dielectric interposer base surrounding the conductive pillars and electrically isolating them from each other. The interposer base may include a dielectric material such as silicon dioxide or a semiconductor material such as silicon, or a polymer material such as epoxy resin with or without fillers. In addition, bottom surfaces of the conductive pillars are exposed from a bottom surface of the interposer base for contacting the solder bumps 111. In some embodiments, multiple conductive pads can be formed on the bottom surface of the conductive pillars for the mounting of the connecting interposer units onto the bridge interposer 101 through the respective solder bumps 111. In the embodiment shown in FIG. 1B, for each of the connecting interposer units, at least one of the conductive pillars included in the connecting interposer unit is attached on one of the conductive wires 103, thereby allowing for the electrical connection between each of the connecting interposer units and the bridge interposer 101. In some embodiments, each of the connecting interposer units may include only one conductive pillar or more than two conductive pillars. Furthermore, top surfaces of the conductive pillars are exposed from a top surface of the interposer base for electrical connection of additional electronic modules. It can be appreciated that the height of the conductive pillars may be smaller than the height of the respective interposer bases, which may leave slots above the top surfaces of the conductive pillars. The slots may be used to accommodate electrical connection structures or solder bumps of additional electronic modules. In some other embodiments, the connecting interposer units may include conductive patterns and/or conductive vias.

Still referring to FIG. 1B, the connecting interposer units include a first connecting interposer unit 110-1 having a smallest height, a second connecting interposer unit 110-2 having a medium height and a third connecting interposer unit 110-3 having a largest height. The connecting interposer units are disposed adjacently according to the increasing heights, thereby defining a step structure on one side of the step interposer 110. In some embodiments, the pairs of adjacent connecting interposer units may have the same height difference or different height differences, which enables the heights of the connecting interposer units to form an arithmetic sequence. In addition, the pairs of the adjacent connecting interposer units have the same distance, thereby the connecting interposer units are uniformly distributed on the bridge interposer 101. In some other embodiments, the height differences between adjacent connecting interposer units may be different. The pairs of adjacent connecting interposer units may also have different distances. It can be appreciated that a different number of connecting interposer units may be attached on the package substrate 100.

Furthermore, as shown in FIG. 1B, each of the connecting interposer units has a cuboid shape, and each of the connecting interposer units has a step surface at top of the connecting interposer unit and a rise surface at a lateral side of the connecting interposer unit. Referring to FIG. 1B, the first connecting interposer unit 110-1 has a first step surface 112-1 at top of the first connecting interposer unit 110-1 and a first rise surface 112-2 extending between the first step surface 112-1 and the top surface of the bridge interposer 101. The second connecting interposer unit 110-2 has a second step surface 113-1 at top of the second connecting interposer unit 110-2 and a second rise surface 113-2 extending between the second step surface 113-1 and the first step surface 112-1. The third connecting interposer unit 110-3 has a third step surface 114-1 at top of the third connecting interposer unit 110-3 and a third rise surface 114-2 extending between the third step surface 114-1 and the second step surface 113-1. The first step surface 112-1, the first rise surface 112-2, the second step surface 113-1, the second rise surface 113-2, the third step surface 114-1 and the third rise surface 114-2 together form the step structure of the step interposer 110.

Next, a bottom semiconductor die 120-1 is mounted on the package substrate 100 and adjacent to the first rise surface 112-2 of the first connecting interposer unit 110-1 via solder bumps 121-1. In the embodiment shown in FIG. 1B, multiple conductive pads may be formed on a bottom surface of the bottom semiconductor die 120-1 for the mounting of the bottom semiconductor die 120-1 onto the package substrate 100 through the respective solder bumps 121-1. To be more specific, the bottom semiconductor die 120-1 may be attached on top surfaces of the top conductive patterns within the package substrate 100 and thereby be electrically connected with the redistribution structures. In some other embodiments, apart from the solder bumps 111 used for electrical connection, there may also be dummy bumps formed underneath the bottom semiconductor die 120-1. Instead of being electrically connected with the top conductive patterns within the package substrate 100, the dummy bumps may only provide mechanical support for the components thereon. In some embodiments, the bottom semiconductor die 120-1 may include a high bandwidth memory die. In some other embodiments, the bottom semiconductor die 120-1 may include a logic die or a controller die such as a micro-processor or micro controller unit.

After the mounting of the bottom semiconductor die 120-1, the height of a top surface of the bottom semiconductor die 120-1 relative to the front surface of the package substrate 100 may be approximately the same as that of the first connecting interposer unit 110-1, which provides a relatively flat platform for mounting of an upper semiconductor die in a following step.

Next, as shown in FIG. 1C, a first upper semiconductor die 120-2 is mounted on both of the first step surface 112-1 of the first connecting interposer unit 110-1 and the bottom semiconductor die 120-1 via solder bumps 121-2. Multiple conductive pads may be formed on a bottom surface of the first upper semiconductor die 120-2 for the mounting of the first upper semiconductor die 120-2 onto the first connecting interposer unit 110-1 and the bottom semiconductor die 120-1 through solder bumps 121-2. In this embodiment, the solder bumps 121-2 may include connecting bumps and dummy bumps. The connecting bumps are used to attach the first upper semiconductor die 120-2 onto the first step surface 112-1. To be more specific, the connecting bumps are attached onto the top surfaces of the conductive pillars within the first connecting interposer unit 110-1. Thereby, the first upper semiconductor die 120-2 can be electrically coupled with the bridge interposer 101 through the first connecting interposer unit 110-1. At the same time, the dummy bumps are attached onto the top surface of the bottom semiconductor die 120-1, which only provide mechanical support for the components thereon instead of providing electrical connections.

As shown in FIG. 1C, after the mounting of the first upper semiconductor die 120-2, the height of the top surface of the first upper semiconductor die 120-2 relative to the front surface of the package substrate 100 may be approximately the same as that of the second step surface 113-1, which provides a relatively flat platform for mounting of an additional upper semiconductor die.

Next, as shown in FIG. 1D, a second upper semiconductor die 120-3 is mounted on both of the second step surface 113-1 of the second connecting interposer unit 110-2 and the first upper semiconductor die 120-2 via solder bumps 121-3. Thereby, the second upper semiconductor die 120-3 may be electrically coupled with the bridge interposer 101 through the second connecting interposer unit 110-2. After the mounting of the second upper semiconductor die 120-3, the height of the top surface of the second upper semiconductor die 120-3 relative to the front surface of the package substrate 100 may be approximately the same as that of the third step surface 114-1. The details of the mounting step of the second upper semiconductor die 120-3 may be similar as the mounting step of the first upper semiconductor die 120-2, which will not be elaborated in detail here for simplicity.

Next, as shown in FIG. 1E, a third upper semiconductor die 120-4 is mounted on both of the third step surface 114-1 of the third connecting interposer unit 110-3 and the second upper semiconductor die 120-3 via solder bumps 121-4. Thereby, the third upper semiconductor die 120-4 may be electrically coupled with the bridge interposer 101 through the third connecting interposer unit 110-3. The details of the mounting step of the third upper semiconductor die 120-4 may be similar as the mounting step of the first upper semiconductor die 120-2, which will not be elaborated in detail here for simplicity.

It can be appreciated that the upper semiconductor dice may include high bandwidth memory dice. In some other embodiments, the upper semiconductor dice may include logic dice or controller dice. In addition, in the embodiment shown in FIG. 1E, the bottom semiconductor die 120-1 and the upper semiconductor dice may have a same shape and size. In some other embodiments, the bottom semiconductor die 120-1 and the upper semiconductor dice may have different shapes or sizes. For example, the bottom semiconductor die 120-1 and the upper semiconductor dice may have different thicknesses. Accordingly, the adjacent connecting interposer units may have different height differences. In other words, the connecting interposer units may be chosen to have respective heights such that the top surface of a connecting interposer unit and the top surface of a semiconductor die adjacent to the connecting interposer unit and at the same level may form a relatively flat plane or platform for mounting of an additional upper semiconductor die. In addition, the bottom semiconductor die 120-1 and the upper semiconductor dice may have different widths. Accordingly, the connecting interposer units may also have different widths to provide sufficient accommodation for the bottom semiconductor die 120-1 and the upper semiconductor dice. In this way, the connecting interposer units may mate with the arrangement of the semiconductor dice in a more flexible manner.

Moreover, in this embodiment, the first connecting interposer unit 110-1, the second connecting interposer unit 110-2 and the third connecting interposer unit 110-3 are attached onto the top surface of the bridge interposer 101 before the mounting of the bottom semiconductor die 120-1 onto the package substrate 100. In some other embodiments, after the attachment of the first connecting interposer unit 110-1 onto the top surface of the bridge interposer 101, the bottom semiconductor die 120-1 may be mounted onto the package substrate 100. Then the second connecting interposer unit 110-2 may be mounted onto the top surface of the bridge interposer 101 before or after the mounting of the first upper semiconductor die 120-2. The third connecting interposer unit 110-3 may be mounted onto the top surface of the bridge interposer 101 before or after the mounting of the second upper semiconductor die 120-3. In this way, the attachment of the connecting interposer units may be more flexible, and the pairs of adjacent connecting interposer units may have the same distance or different distances, which can be adjusted according to the size and shape of the attached semiconductor dice. In addition, the connecting interposer units may include conductive patterns and/or conductive vias to provide more flexible layouts for the electrical connection between the upper semiconductor dice and the bridge interposer 101. In some other embodiments, additional connecting interposer unit(s) may be mounted on the bridge interposer 101, and additional upper semiconductor die (dice) may be partially mounted on respective step surfaces of the additional connecting interposer unit(s).

In some other embodiments, before attaching the connecting interposer units, the bottom semiconductor die 120-1 and the upper semiconductor dice onto the top surface of the bridge interposer 101 and the front surface of the package substrate 100, a frame (not shown) may be attached onto the top surface of the bridge interposer 101 and the front surface of the package substrate 100. The frame may include a plurality of vertical partitions or grids each corresponding to one of the connecting interposer units or one of the semiconductor dice, thereby assisting the attachment of the connecting interposer units and the semiconductor dice. To be more specific, during the step of attaching the connecting interposer units, each of the connecting interposer units may be attached on the top surface of the bridge interposer 101 by leaning a left lateral surface against a lateral surface or wall of a respective vertical partition of the frame. Similarly, each of the semiconductor dice may be attached on the front surface of the package substrate 100 by leaning a right lateral surface against a lateral surface or wall of a respective vertical partition of the frame. In this way, the frame may help to fix the connecting interposer units and the semiconductor dice on the substrate. In addition, the vertical partitions may avoid potential tilting of the connecting interposer units during the attaching process of the connecting interposer units onto the bridge interposer 101. The number of the vertical partitions included in the frame may vary depending on how the connecting interposer units and/or the semiconductor dice are secured by the frame. For example, the frame may include vertical partitions each corresponding to one of the connecting interposer units, which may be similar to a comb structure that is inserted into the spaces between the connecting interposer units. Alternatively, the frame may include only two partitions which correspond to a periphery of the combination of the connecting interposer units and the semiconductor dice, which may be similar to a clamp structure.

Moreover, after attaching the connecting interposer units and the semiconductor dice on the package substrate 100, a chase may be applied on the top surfaces of the third connecting interposer unit 110-3 and the third upper semiconductor die 120-4. Then the connecting interposer units and the semiconductor dice are pressed against the bridge interposer 101 and the package substrate 100 by the chase to reshape the solder bumps beneath the connecting interposer units and the semiconductor dice, which may keep the top surfaces of connecting interposer units and the top surfaces of the semiconductor dice parallel to the front surface of the package substrate 100. At the same time, the pressing step may align the top surfaces of connecting interposer units with the top surfaces of the respective semiconductor dice which are at the same level with the connecting interposer units, thereby improving surface uniformity of the stacked semiconductor dice. During the pressing step, the frame may also serve as a barrier which limits the tilting and displacement of the connecting interposer units and the semiconductor dice relative to the package substrate, thereby maintaining the alignment of the connecting interposer units and the semiconductor dice with the conductive patterns or pads on the package substrate 100. It can be appreciated that the pressing step may be implemented before or during a reflowing process of the solder bumps. Also, the solder bumps may exhibit deformable characteristics which may be reshaped by external forces. In some alternative embodiments when the connecting interposer units and the semiconductor dice at the same level are attached successively, a pressing step may be applied after each pair of the connecting interposer unit and the respective semiconductor die at the same level is attached.

In the embodiment shown in FIG. 1F, an electronic component 130 is mounted on the top surface of the bridge interposer 101. Multiple conductive pads may be formed on a bottom surface of the electronic component 130 for the mounting of the electronic component 130 onto the bridge interposer 101 through solder bumps 131. To be more specific, at least some of the solder bumps 131 may be attached on the second conductive pads of the conductive wires 103 included in the bridge interposer 101 to electrically connect the electronic component 130 with the bridge interposer 101. In this way, the electronic component 130 may be electrically coupled with each of the upper semiconductor dice via the bridge interposer 101 and the step interposer 110. In some embodiments, at least one of the solder bumps 131 may be electrically connected with the top conductive patterns within the package substrate 100, which may electrically couple the electronic component 130 with the bottom semiconductor die 120-1 via the redistribution structures within the package substrate 100. In some other embodiments, solder bumps 131 may also include dummy bumps which only provide mechanical support for the attachment of the electronic component 130 on the package substrate 100.

Furthermore, in this embodiment, the electronic component 130 includes an SOC die. In some other embodiments, the electronic component 130 may include various types of electronic modules, such as semiconductor chips, resistors, capacitors or the like. In some other embodiments, extra electronic component(s) may be mounted onto the bridge interposer 101. The bridge interposer 101 may include additional electrical connection structures to electrically couple extra electronic component(s) with the upper semiconductor dice.

Moreover, in the embodiment in FIG. 1F, a top surface of the electronic component 130 may have a height higher than that of the third upper semiconductor die 120-4. In some other embodiments, the top surface of the electronic component 130 may have a height approximately the same as that of the third upper semiconductor die 120-4.

Next, a bonding process such as laser assisted bonding or mass reflow may be performed to bond each of the semiconductor dice with the semiconductor die on the lower layer to form a semiconductor dice stack. In this way, the semiconductor dice stack may have a better stability and thus can serve as a base for further attachment of additional layers of components and structures thereon. Similarly, a bonding process may also be performed to bond the electronic component 130 internally or externally with additional components.

As shown in FIG. 1G, a mold cap 140 is formed on the package substrate 100 to encapsulate the bottom semiconductor die 120-1, the upper semiconductor dice 120-2, 120-3, 120-4, the step interposer 110 and the electronic component 130. The mold cap 140 may be formed using a molding process such as an injection molding process, which covers respective top surfaces and lateral surfaces of the structures and components on the package substrate 100. The mold cap material may include epoxy, polyester resin, etc. In some embodiments, the mold cap 140 may be formed using various other molding technologies, including a transfer molding process, a compression molding process or a film-assisted molding (FAM) process. Afterwards and optionally, a grinding process may be performed to remove the mold cap material on the top surface of the electronic component 130 to expose the top surface of the electronic component 130, thereby forming the electronic device 160. In some other embodiments where a frame is attached before the attaching of the step interposer and the semiconductor dice as mentioned above, the frame may include the same or similar material as that of the mold cap 140. After the formation of the mold cap 140, the frame and the mold cap 140 may merge together to form an integrated piece. In some alternative embodiments, the frame may include a different material from the mold cap 140, such as a metal material or a ceramic material. Then the frame may be optionally removed before the formation of the mold cap 140.

Next, still referring to FIG. 1G, additional solder bumps 150 may be formed on the back surface of the package substrate 100 for mounting of the electronic device 160 onto external electronic modules. The solder bumps 150 may be electrically connected with the bridge interposer 101 and the redistribution structures in the package substrate 100, such that the semiconductor dice 120-1 to 120-4 and the electronic component 130 can be accessed through the solder bumps 150.

The fabrication process of the electronic device 160 according to FIGS. 1A to 1G offers multiple advantages. Firstly, the attaching process of the multiple connecting interposer units on the bridge interposer 101 may be more flexible since the heights of the connecting interposer units, the widths the connecting interposer units and the distance between each pair of adjacent connecting interposer units may be easily adjusted according to the shapes and sizes of the bottom semiconductor die 120-1 and the upper semiconductor dice, which is beneficial to the electronic device 160 with complex electrical connection layouts. The connecting interposer units may also include more complicated electrical connection pathways to electrically connect the upper semiconductor dice with the electronic component 130. Secondly, the bottom semiconductor die 120-1 and the upper semiconductor dice are stacked together at a die level to form a chiplet semiconductor structure, and the electronic component 130 and the chiplet semiconductor structure may be encapsulated in a single molding step, which greatly simplifies the packaging process, reduces cost and allows for a fine bump pitch for high performance devices. The final electronic device 160 may be tested for only once since a single molding step is conducted. Thirdly, since the bottom semiconductor die 120-1 and the upper semiconductor dice may form the chiplet semiconductor structure instead of a pre-molded semiconductor package, the fabrication process may avoid an otherwise package-in-package structure, thereby alleviating the warpage of the whole electronic device during a subsequent heating process such as solder bumps reflowing processes. Fourthly, the bridge interposer 101 and the step interposer 110 may simplify the electronical connection between the electronic component 130 and the upper semiconductor dice, which improves electrical stability and saves assembly space.

In some embodiments, the electronic device 160 can be applied in any semiconductor device which desire reduced fabrication cost and high performance, such as in high-sensitive sensors, precise integrated memory devices or the like.

In some other embodiments, the step interposer mounted on the top surface of the bridge interposer 101 may include an integrated step interposer instead of a plurality of separated connecting interposer units as illustrated in FIGS. 1A to 1G.

FIG. 2 illustrates an electronic device 260 according to a second embodiment of the present application.

As shown in FIG. 2, a package substrate 200 is provided and a bridge interposer 201 is formed within the package substrate 200. An integrated step interposer 210 is mounted on the top surface of the bridge interposer 201. The integrated step interposer 210 may include three interposer layers, namely, a first interposer layer, a second interposer layer on the first interposer layer and a third interposer layer on the second interposer layer. The three interposer layers are integrated together as the step interposer 210 in form of a single piece. The integrated step interposer 210 may be formed by removing a portion of a substrate, for example, using milling, drilling, pinching, etching or their combinations.

Still referring to FIG. 2, the integrated step interposer 210 defines a step structure on one side of the integrated step interposer 210. To be more specific, the first interposer layer includes an exposed first step surface at the top of the first interposer layer and a first rise surface extending between the first step surface and the top surface of the bridge interposer. The second interposer layer includes an exposed second step surface at top of the second interposer layer and a second rise surface extending between the second step surface and the first step surface. The third interposer layer includes an exposed third step surface at top of the third interposer layer structure and a third rise surface extending between the third step surface and the second step surface. The first step surface, the first rise surface, the second step surface, the second rise surface, the third step surface and the third rise surface together compose the step structure of the integrated step interposer 210. Moreover, the integrated step interposer 210 may include multiple conductive pillars 210-1 and an interposer base 210-2 surrounding the conductive pillars 210-1. Each of the conductive pillars 210-1 is extending from one of the step surfaces to a bottom surface of the interposer base 210-2. In some other embodiments, the integrated step interposer 210 may include through glass vias (TGV) when the interposer base 210-2 is mainly made of glass with the conductive pillars 210-1 extending vertically through the entire step interposer 210.

A bottom semiconductor die 220-1 is mounted on the package substrate 200 and adjacent to the step interposer 210, and three upper semiconductor dice 220-2, 220-3, 220-4 may be partially mounted on the respective step surfaces of the interposer layers. Further, an electronic component 230 is mounted on the top surface of the bridge interposer 201. A mold cap 240 is formed on the package substrate 200 to encapsulate the bottom semiconductor die 220-1, the upper semiconductor dice, the step interposer 210 and the electronic component 230. In some other embodiments, the integrated step interposer 210 may include more than three interposer layers, and additional upper semiconductor die (dice) may be partially mounted on respective step surfaces of the additional interposer layers.

Further details of the electronic device 260 may be similar to those illustrated in the embodiment in FIGS. 1A to 1G, which will not be elaborated in detail here for simplicity.

For the formation of the electronic device 260, since the step interposer 210 is an integrated unit, the fabrication and attachment of the step interposer 210 onto the bridge interposer 101 may be greatly simplified. In addition, the upper semiconductor dice may be stacked on the step structure of the step interposer 210 in a more stable manner.

In an alternative embodiment, the step interposer 210 may include two or more interposer layers on the top surface of the bridge interposer 201. The two or more separated interposer layers may be separated pieces, which may be successively attached on the top surface of the bridge interposer 201. A bonding process may be conducted to bond each of the interposer layers with a lower interposer layer. In particular, each of the two or more interposer layers may have a top surface that is at least partially exposed as a step surface of the step structure and a rise surface extending between two of the step surfaces or between a step surface and the top surface of the bridge interposer 201.

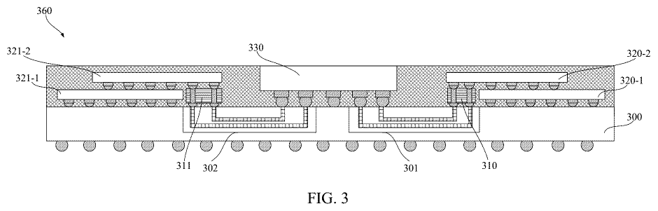

FIG. 3 illustrates an electronic device 360 according to a third embodiment of the present application.

As shown in FIG. 3, a package substrate 300 is provided and a bridge interposer 301 is formed within the package substrate 300. A step interposer 310 is mounted on the top surface of the bridge interposer 301, defining a step structure on one side of the step interposer 310. The step interposer 310 includes one connecting interposer unit 310 having a step surface at top of the connecting interposer unit 310 and a rise surface extending from the top surface of the bridge interposer 301 to the step surface. A bottom semiconductor die 320-1 is mounted on the package substrate 300 and adjacent to the connecting interposer unit 310. An upper semiconductor die 320-2 is mounted on both of the step surface of the connecting interposer unit 310 and the bottom semiconductor die 320-1. Furthermore, an additional bridge interposer 302 is formed within the package substrate 300 and a top surface of the additional bridge interposer 302 is exposed from the package substrate 300. An additional step interposer 311 may be mounted on the top surface of the additional bridge interposer 302, which defines a step structure on one side of the additional step interposer 311. The additional step interposer 311 may include one additional connecting interposer unit 311, which is similar to the connecting interposer unit 310. An additional bottom semiconductor die 321-1 may be mounted on the package substrate 300 and adjacent to the additional step interposer 311, and an additional upper semiconductor die 321-2 may be mounted on both of the additional bottom semiconductor die 321-1 and the step surface of the additional connecting interposer unit 311 to electrically couple the additional upper semiconductor die 321-2 with the additional bridge interposer 302 through the additional connecting interposer unit 311. Further an electronic component 330 is mounted on the top surface of the bridge interposer 301 and on the top surface of the additional bridge interposer 302 such that the electronic component 330 is electrically coupled with the upper semiconductor die via the bridge interposer 301 and the step interposer 310, and the electronic component 330 is also electrically coupled with the additional upper semiconductor die 321-2 via the additional bridge interposer 302 and the additional step interposer 311, thereby the electronic device 360 is formed. Since the semiconductor dice may be separated into two stacks of chiplet semiconductor structures, the height of each of the semiconductor dice stacks may be reduced, enabling more spare room for extra electronic modules. The electronic device 360 may be applied in any semiconductor devices which desire a high integration level and a minimized size such as mobile phones and tablets. In some other embodiments, the step interposer 310 and the additional step interposer 311 may be similar to any of the step interposers which are illustrated previously with reference to FIGS. 1A to 1G and FIG. 2. Accordingly, the number of the semiconductor dice included in one stack may be more than two. Also, the structure of the step interposer 310 and the additional step interposer 311 may be different, and the number of the semiconductor dice included in different semiconductor dice stacks may be different.

Further details of structures and forming steps of the electronic device 360 may be similar to those illustrated in the embodiment in FIGS. 1A to 1G, which will not be elaborated in detail here for simplicity.

In the embodiment shown in FIG. 3, the bridge interposer 301 and additional bridge interposer 302 may be formed on two opposite sides of the electronic component 330. In some other embodiments, the bridge interposer 301 and the additional bridge interposer 302 may be formed on different positions on the same side of the electronic component 330. Furthermore, in some other embodiments, extra bridge interposers may be formed on the package substrate 300 to serve as additional platforms for formation of more semiconductor dice stacks, which may further minimize the size of the electronic device 360.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a package substrate;
forming a bridge interposer within the package substrate and exposing a top surface of the bridge interposer from the package substrate;
attaching a step interposer on the top surface of the bridge interposer, wherein the step interposer defines a step structure on one side of the step interposer;
mounting a bottom semiconductor die on the package substrate and adjacent to the step interposer;
mounting one or more upper semiconductor dice on both of the bottom semiconductor die and the step structure of the step interposer to electrically couple each of the upper semiconductor dice with the bridge interposer through the step interposer;
mounting an electronic component on the top surface of the bridge interposer to electrically couple the electronic component with the one or more upper semiconductor dice via the bridge interposer and the step interposer; and
forming a mold cap on the package substrate to encapsulate the bottom semiconductor die, the one or more upper semiconductor dice, the step interposer and the electronic component.

2. The method of claim 1, wherein the electronic component comprises a system on a chip die.

3. The method of claim 1, wherein the bottom semiconductor die comprises a high bandwidth memory die, and the one or more upper semiconductor dice comprise one or more high bandwidth memory dice.

4. The method of claim 1, wherein the step interposer comprises a connecting interposer unit, and the step structure on one side of the step interposer comprises:
a step surface at top of the connecting interposer unit and a rise surface extending from the top surface of the bridge interposer to the step surface.

5. The method of claim 4, wherein mounting one or more upper semiconductor dice on both of the bottom semiconductor die and the step structure of the step interposer comprises:
mounting an upper semiconductor die on both of the step surface of the connecting interposer unit and the bottom semiconductor die.

6. The method of claim 1, wherein attaching a step interposer on the top surface of the bridge interposer comprises:
juxtaposing on the top surface of the bridge interposer a plurality of connecting interposer units having successively increasing heights and each having a step surface and a rise surface to form the step interposer, wherein the step structure comprises two or more step surfaces and two or more rise surfaces each extending between two of the step surfaces or between a step surface and the top surface of the bridge interposer.

7. The method of claim 6, wherein mounting one or more upper semiconductor dice on both of the bottom semiconductor die and the step structure of the step interposer comprises:
mounting two or more upper semiconductor dice partially on the respective step surfaces of the connecting interposer units.

8. The method of claim 1, wherein attaching a step interposer on the top surface of the bridge interposer comprises:
attaching successively two or more interposer layers on the top surface of the bridge interposer, wherein each of the two or more interposer layers has a top surface that is at least partially exposed as a step surface of the step structure and a rise surface extending between two of the step surfaces or between a step surface and the top surface of the bridge interposer.

9. The method of claim 1, wherein attaching a step interposer on the top surface of the bridge interposer comprises:
attaching an integrated step interposer on the top surface of the bridge interposer, wherein the integrated step interposer comprises a plurality of interposer layers each having an exposed step surface at the step structure and a rise surface extending between two of the step surfaces or between a step surface and the top surface of the bridge interposer.

10. The method of claim 8, wherein mounting one or more upper semiconductor dice on both of the bottom semiconductor die and the step structure of the step interposer comprises:
mounting two or more upper semiconductor dice partially on the respective step surfaces of the interposer layers.

11. The method of claim 1, before mounting an electronic component on the top surface of the bridge interposer, the method further comprising:
forming an additional bridge interposer within the package substrate and exposing a top surface of the additional bridge interposer from the package substrate;
attaching an additional step interposer on the top surface of the additional bridge interposer, wherein the additional step interposer defines a step structure on one side of the additional step interposer;
mounting an additional bottom semiconductor die on the package substrate and adjacent to the additional step interposer; and
mounting one or more additional upper semiconductor dice on both of the additional bottom semiconductor die and the step structure of the additional step interposer to electrically couple each of the one or more additional upper semiconductor dice with the additional bridge interposer through the additional step interposer.

12. An electronic device, comprising:
a package substrate;
a bridge interposer formed within the package substrate, wherein the bridge interposer comprises a top surface exposed from the package substrate;
a step interposer attached on the top surface of the bridge interposer, wherein the step interposer defines a step structure on one side of the step interposer;
a bottom semiconductor die mounted on the package substrate and adjacent to the step interposer;
one or more upper semiconductor dice mounted on both of the bottom semiconductor die and the step structure of the step interposer, wherein each of the one or more upper semiconductor dice is electrically coupled with the bridge interposer through the step interposer;
an electronic component mounted on the top surface of the bridge interposer, wherein the electronic component is electrically coupled with the one or more upper semiconductor dice via the bridge interposer and the step interposer; and
a mold cap formed on the package substrate and encapsulating the bottom semiconductor die, the one or more upper semiconductor dice, the step interposer and the electronic component.

13. The electronic device of claim 12, wherein the step interposer comprises a connecting interposer unit, and the step structure on one side of the step interposer comprises:
a step surface at top of the connecting interposer unit and a rise surface extending from the top surface of the bridge interposer to the step surface.

14. The electronic device of claim 13, wherein an upper semiconductor die is mounted on both of the step surface of the connecting interposer unit and the bottom semiconductor die.

15. The electronic device of claim 12, wherein the step interposer comprises:
a plurality of connecting interposer units having successively increasing heights juxtaposed on the top surface of the bridge interposer, wherein each of the connecting interposer units comprises a step surface and a rise surface to form the step interposer, and the step structure comprises two or more step surfaces and two or more rise surfaces each extending between two of the step surfaces or between a step surface and the top surface of the bridge interposer.

16. The electronic device of claim 15, wherein the electronic device further comprises: two or more upper semiconductor dice mounted partially on the respective step surfaces of the connecting interposer units.

17. The electronic device of claim 12, wherein the step interposer comprises:
two or more interposer layers successively attached on the top surface of the bridge interposer, wherein each of the two or more interposer layers has a top surface that is at least partially exposed as a step surface of the step structure and a rise surface extending between two of the step surfaces or between a step surface and the top surface of the bridge interposer.

18. The electronic device of claim 12, wherein the step interposer comprises:
an integrated step interposer attached on the top surface of the bridge interposer, wherein the integrated step interposer comprises a plurality of interposer layers each having an exposed step surface at the step structure and a rise surface extending two of the step surfaces or between a step surface and the top surface of the bridge interposer.

19. The electronic device of claim 17, wherein the electronic device further comprises: two or more upper semiconductor dice mounted partially on the respective step surfaces of the interposer layers.

20. The electronic device of claim 12, further comprising:
an additional bridge interposer formed within the package substrate, wherein the additional bridge interposer comprises a top surface exposed from the package substrate;
an additional step interposer attached on the top surface of the bridge interposer, wherein the additional step interposer defines a step structure on one side of the additional step interposer;
an additional bottom semiconductor die mounted on the package substrate and adjacent to the additional step interposer; and
one or more additional upper semiconductor dice mounted on both of the additional bottom semiconductor die and the step structure of the additional step interposer, wherein each of the one or more additional upper semiconductor dice is electrically coupled with the additional bridge interposer through the additional step interposer.
